(19) United States
(12) Patent Application Publication
(10) Pub. No.: US 2022/0408562 A1
(43) Pub. Date: Dec. 22, 2022

(54) INTEGRATED RF PASSIVE DEVICES ON GLASS

(71) Applicant: Intel Corporation, Santa Clara, CA (US)

(72) Inventors: Telesphor KAMGAING, Chandler, AZ (US); Georgios C. DOGIAMIS, Chandler, AZ (US); Neelam PRABHU GAUNKAR, Chandler, AZ (US); Veronica STRONG, Hillsboro, OR (US); Aleksandar ALEKSOV, Chandler, AZ (US)

(21) Appl. No.: 17/349,700

(22) Filed: Jun. 16, 2021

(51) Int. Cl. H05K 1/11; H05K 1/03

(52) U.S. Cl. CPC H05K 1/112; H05K 1/0306; H05K 2201/10098; H05K 2201/09481

(57) ABSTRACT

Embodiments disclosed herein include package substrates and methods of forming such package substrates. In an embodiment a package substrate comprises a glass core, and a vertically oriented inductor embedded in the glass core. In an embodiment, the inductor comprises vertical vias through the glass core, and where the vertical vias are electrically coupled together by conductive traces over a surface of the glass core to provide a plurality of conductive turns.

### TECHNICAL FIELD

Embodiments of the present disclosure relate to electronic packages, and more particularly to package substrates with a glass core with embedded RF passives.

### BACKGROUND

Integrated RF passives are widely used in modern wireless communication systems as part of the RF front-end-module filter and matching circuits. Integrated passive devices (IPDs) currently used include inductors, transformers, and capacitors. However, such IPDs occupy a substantial part of the real estate on electronic packages. As such, there are significant limitations to high-density integrations. IPDs are still needed in portable devices, including always connected PCs (ACPCs), notebooks, smartphones, and tablets, where real estate is extremely limited.

IPDs on organic substrates are limited, in part, due to process variations associated with non-uniform dielectric thicknesses between layers. In addition, to process variation limitations, planar inductors and capacitors utilize a large substrate area. IPDs have been integrated on glass substrates, but there are still issues. Currently, only horizontally oriented passives have been used. For example, metal-insulator-metal (MIM) capacitors have been produced. However, MIM capacitors are very sensitive to layer deposition techniques. Inductors on glass are also planar, and have not been integrated at a pitch that significantly enhances the electromagnetic coupling and associated mutual inductance needed for high performance devices.

### BRIEF DESCRIPTION OF THE DRAWINGS

FIG. 1A is a cross-sectional illustration of a glass core with top and bottom surfaces that are being exposed with a laser, in accordance with an embodiment.

FIG. 1B is a cross-sectional illustration of the glass core with regions that have their morphology altered by the laser, in accordance with an embodiment.

FIG. 1C is a cross-sectional illustration of the glass core with a via hole through a thickness of the glass core, in accordance with an embodiment.

FIG. 1D is a cross-sectional illustration of the glass core with a via through the thickness of the glass core, in accordance with an embodiment.

FIG. 2A is a plan view illustration of the glass core with a plurality of circular vias, in accordance with an embodiment.

FIG. 2B is a plan view illustration of the glass core with a vertical via plane, in accordance with an embodiment.

FIG. 3 is a cross-sectional illustration of an electronic package that includes a package substrate with integrated passive devices (IPDs) that are embedded in a core, in accordance with an embodiment.

FIG. 4A is a perspective view illustration of a vertically oriented inductor with a plurality of loops that are substantially orthogonal to a top surface of the package core, in accordance with an embodiment.

FIG. 4B is a perspective view illustration of a vertically oriented capacitor with a pair of conductive planes that extend into the package core, in accordance with an embodiment.

FIG. 5A is a cross-sectional illustration of a core with a plurality of capacitors with different dimensions and capacitances, in accordance with an embodiment.

FIG. 5B is a cross-sectional illustration of a core with an embedded capacitor with interdigitated fingers, in accordance with an embodiment.

FIG. 6A is a cross-sectional illustration of a core with an inductor loop with vertical vias that have hourglass shaped cross-sections, in accordance with an embodiment.

FIG. 6B is a cross-sectional illustration of a core with an embedded capacitor with vertical planes that have hourglass shaped cross-sections, in accordance with an embodiment.

FIG. 7A is cross-sectional illustration of a die module that includes discrete IPDs with vertically oriented passives embedded in a glass core, in accordance with an embodiment.

FIG. 7B is a cross-sectional illustration of a die module with discrete IPDs with vertically oriented passives embedded in a glass core that are attached on a bottom surface of the die, in accordance with an embodiment.

FIG. 8 is a cross-sectional illustration of an electronic system with a package substrate that comprises a glass core with vertically oriented passive devices embedded in the glass core, in accordance with an embodiment.

FIG. 9 is a schematic of a computing device built in accordance with an embodiment.

### EMBODIMENTS OF THE PRESENT DISCLOSURE

Described herein are package substrates with a glass core with embedded RF passives, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, integrated passive devices (IPDs) are currently available technologies. However, existing IPDs are horizontally oriented passives. Such devices take up substantial real estate on a package substrate. Additionally, the horizontal nature of the passive devices limits the ability to form strong electromagnetic coupling and associated mutual inductance. As such, inductors and transformers using such technologies are limited in performance.

Accordingly, embodiments disclosed herein include IPDs that are vertically oriented in the core. Vertically orienting the passives allows for increased densities and improved performances. Additionally, laser-assisted etching processes are used to fabricate the IPDs. Such processing allows for small pitches between conductive features. As such, densities can be improved even further.

Laser-assisted etching processes include exposing the core to a laser. The laser exposure results in a morphological change to the core. The morphological change provides a change in the etch resistance of the core. As such, the exposed regions can be etched away without significantly removing the unexposed regions of the core. Conductive material may then be disposed in the opening into the core to form a passive device, such as an inductor, a transformer, a capacitor, or the like.

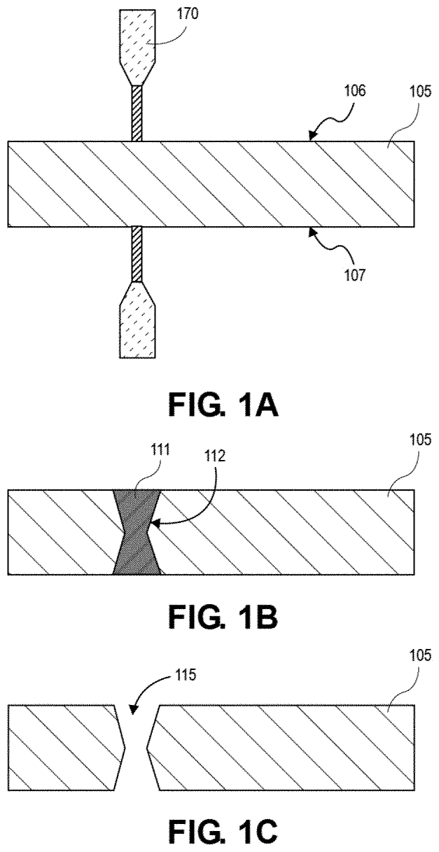

Referring now to FIGS. 1A-1D, a series of cross-sectional illustrations depicting a laser-assisted etching process to form features in a package core is shown, in accordance with an embodiment. The laser-assisted etching process may be used to form various features (e.g., capacitors, inductors, transformers, etc.) described herein. As shown in FIG. 1A, the package core 105 is exposed by a laser 170. The laser 170 may be irradiated over both a first surface 106 and a second surface 107. However, the laser 170 may only irradiate a single surface of the package core 105 in other embodiments.

In an embodiment, the package core 105 may comprise a material that is capable of forming a morphological change as a result of the exposure by the laser 170. For example, in the case of a glass package core 105, the morphological change may result in the conversion of an amorphous crystal structure to a crystalline crystal structure. In an embodiment, the package core 105 may have a thickness between the first surface 106 and the second surface 107 that is between 100 μm and 1,000 μm. However, it is to be appreciated that larger or smaller thicknesses may also be used for the package core 105 in other embodiments.

Referring now to FIG. 1B, a cross-sectional illustration of the package core 105 after the morphological change has occurred is shown, in accordance with an embodiment. As shown, an exposed region 111 is provided through a thickness of the package core 105. In an embodiment, the exposed region 111 may have sidewalls 112 that are sloped. That is, the sidewalls 112 may not be substantially vertical (with respect to the first surface 106 and the second surface 107). In a particular embodiment, the exposed region 111 may have an hourglass shaped cross-section that results from exposure on both the first surface 106 and the second surface 107. As used herein, an hourglass shaped cross section may refer to a shape that starts with a first width on a first end, decreases in width while moving away from the first end until reaching a minimum width between the first end and a second end, and increasing in width while moving from the minimum width in the middle towards the second end. That is, the shape may have a middle region that is narrower in width than the widths of the opposing ends. In an embodiment, the sidewalls 112 may have a slope that is approximately 10° or less away from vertical. While shown with sloped sidewalls 112, it is also to be appreciated that embodiments may include substantially vertical sidewalls depending on the laser parameters and the material of the package core 105.

While shown as providing an exposed region 111 that passes through an entire thickness of the package core 105, it is to be appreciated that laser parameters may be modified in order to provide different structures. For example, a blind structure may be formed. A blind structure extends into, but not through, the package core 105. Furthermore, while shown as being substantially vertically oriented, the exposed region 111 may be at an angle with respect to a surface of the package core 105.

Referring now to FIG. 1C, a cross-sectional illustration of the package core 105 after the exposed region 111 is removed to form a hole 115 through the package core 105 is shown, in accordance with an embodiment. In an embodiment, the hole 115 may be formed with an etching process that is selective to the exposed region 111 over the remainder of the package core 105. The etch selectivity of the exposed region 111 to the remainder of the package core 105 may be 10:1 or greater, or 50:1 or greater. That is, while selective to the exposed region 111, some portion of the package core 105 may also be etched, resulting in the thickness of the package core 105 being slightly reduced. In an embodiment, the etchant may be a wet etching chemistry.

Referring now to FIG. 1D, a cross-sectional illustration of the core substrate 105 after a via 117 is formed in the hole 115 is shown, in accordance with an embodiment. In an embodiment, the via 117 may be deposited with a plating process or any other suitable deposition process. In an embodiment, the hole 115 may have a maximum diameter that is approximately 100 μm or less, approximately 50 μm or less, or approximately 10 μm or less. The pitch between individual holes 115 in the package core 105 may be between approximately 10 μm and approximately 100 μm in some embodiments. The small diameters and pitch (compared to traditional plated through hole (PTH) vias that typically have diameters that are 100 μm or larger and pitches that are 100 μm or larger) allow for high density integration of vias.

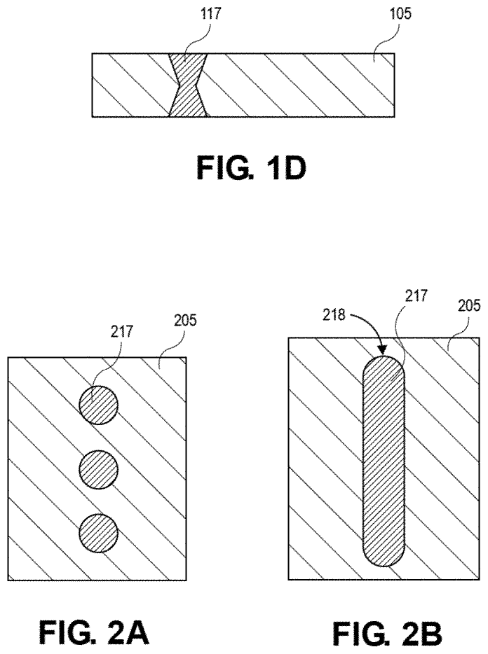

In FIGS. 1A-1D only a single cross-section of the package core 105 is shown for simplicity. However, it is to be appreciated that the shape of the vias 117 may take substantially any form. This is because the laser providing the morphological change in the package core 105 may be moved in a controllable manner. Examples of various plan views of a via 217 in a package core 205 are shown in FIGS. 2A and 2B.

Referring now to FIG. 2A, a plan view illustration of a package core 205 with a plurality of circular vias 217 is shown, in accordance with an embodiment. While three vias 217 are shown, it is to be appreciated that any number of vias 217 may be provided in any configuration.

Referring now to FIG. 2B, a plan view illustration of a package core 205 with a via 217 that is extended along one direction is shown, in accordance with an embodiment. Such a via 217 may be referred to herein as a “via plane” or simply a “plane”. The via plane 217 may have a thickness through the package core 205 that is substantially uniform, while also being extended in a direction, as opposed to having a width and length that are substantially uniform. As shown in FIG. 2B, the ends of the via structure 217 may be rounded surfaces 218. The rounded surfaces may be the result of the shape of the laser irradiation. That is, the focus of the laser may be substantially circular in some embodiments. Via planes may be used to form features such as capacitor plates, as will be described in greater detail below.

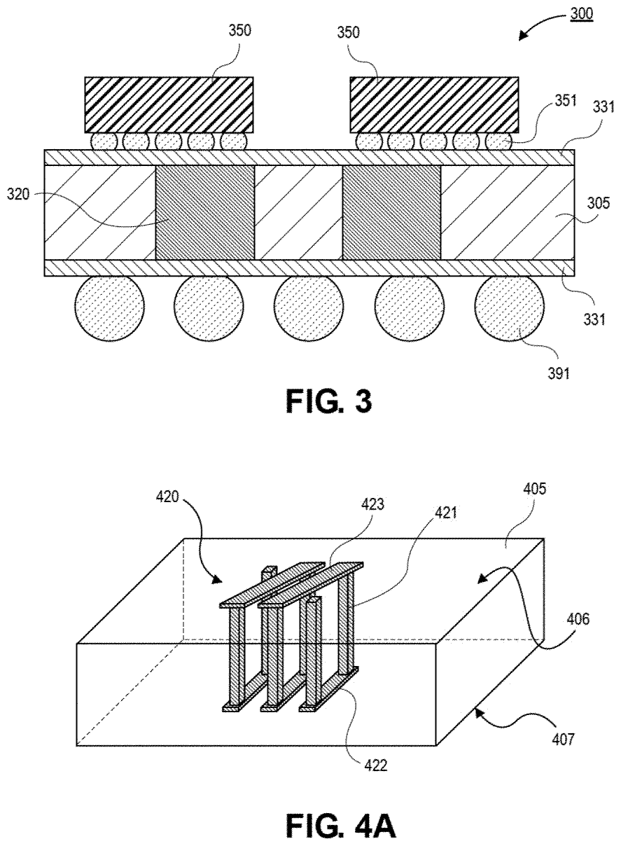

Referring now to FIG. 3, a cross-sectional illustration of an electronic package 300 is shown, in accordance with an embodiment. In an embodiment, the electronic package 300 may comprise a package substrate with a core 305. Buildup layers 331 may be provided above and/or below the core 305. In an embodiment, the core 305 comprises a material that can be patterned with a laser-assisted etching process, such as the one described in greater detail above. For example, the core 305 may comprise glass. In an embodiment, interconnects 391 are provided below the core 305. The interconnects 391 may provide coupling to a board (not shown). For example, the interconnects 391 may comprise solder balls or other second level interconnects. In an embodiment, one or more dies 350 are provided over the core 305. The dies 350 may be coupled to the buildup layer 331 by first level interconnects (FLIs) 351. In an embodiment, the dies 350 may be processors, radio transceivers, amplifiers, system on a chip (SoC) dies, graphics processors, memory, or any other type of computational die 350.

In an embodiment, integrated passive devices (IPDs) 320 may be embedded in the package core 305. That is, the IPDs 320 are fabricated as part of the core, as opposed to a discrete component that is fabricated elsewhere and placed inside a cavity formed in the core. The IPDs 320 are illustrated in FIG. 3 as a generic block for simplicity. More detailed illustrations of the structure of the IPDs 320 are provided in greater detail below. The IPDs 320 may comprise any type of passive device, such as, but not limited to, resistors, capacitors, inductors, and transformers. The IPDs 320 may be fabricated in the core 305 using laser-assisted etching processes, such as those described in greater detail above.

In an embodiment, the IPDs 320 are vertically oriented in the core 305. Vertically oriented refers to the planar component of the IPD 320 being oriented substantially orthogonal to a top surface of the core 305. For example, in the case of an inductor, the turns (or loops) of the inductor are substantially orthogonal to the top surface of the core 305. In the case of a capacitor, the conductive plates are substantially orthogonal to the top surface of the core 305.

In an embodiment, the passives on the IPDs 320 may be connected together to form functional circuitry. For example, the passives on the IPDs 320 may be connected together to provide functions such as filtering, matching, duplexing, or the like. In a particular embodiment, the functional circuitry formed by the passives of the IPDs 320 are part of an RF front-end module for wireless communication systems of the electronic package 300.

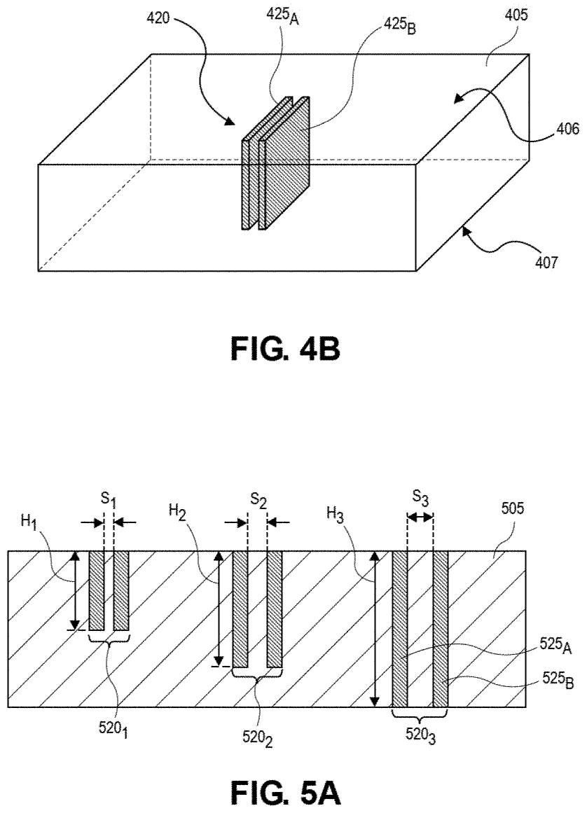

Referring now to FIG. 4A, a perspective view illustration of an IPD 420 in a core 405 is shown, in accordance with an embodiment. In an embodiment, the IPD 420 is an inductor. The inductor IPD 420 comprises a plurality of turns, and the turns are oriented substantially orthogonal to a top surface 406 of the core 405. In the particular embodiment shown in FIG. 4A, three turns are shown. However, it is to be appreciated that any number of turns may be used in order to provide the desired inductance.

In an embodiment, each turn may comprise a pair of vertical vias 421. The vertical vias 421 may be fabricated using a laser-assisted etching process, such as the one described in greater detail above. In the illustrated embodiment, the vertical vias 421 have substantially vertical sidewalls. However, it is to be appreciated that the vertical vias 421 may also comprise sloped sidewalls. In some embodiments, a cross-section of the vertical vias 421 may be hourglass shaped. In another embodiment, the vertical vias 421 may be via planes (e.g., similar to the via plane 217 in FIG. 2B). Such via planes may decrease the series resistance and increase the quality factor Q of the inductors. The pair of vertical vias 421 may be electrically coupled together by a trace 422. The trace 422 may be disposed in direct contact with a bottom surface 407 of the core 405. In other embodiments, the trace 422 may be provided in a buildup layer (not shown) below the core 405. In an embodiment, adjacent turns are electrically coupled together by a trace 423. The trace 423 may be over the top surface 406 of the core 405. In other embodiments, the trace 423 may be provided in a buildup layer (not shown) over the core 405.

Space savings and improved performance can be provided through the laser-assisted etching process used to form the inductor IPD 420. Particularly, the vias 421 may be fabricated at a tight pitch. For example, the pitch between turns may be approximately 40 μm or smaller. In an additional embodiment, the turns may have a pitch that is approximately 30 μm or smaller. Diameters of the vias 421 may be approximately 50 μm or smaller, or approximately 20 μm or smaller. While a single inductor IPD 420 is shown, it is to be appreciated that a pair of inductor IPDs 420 may be interlaced or otherwise coupled together in order to form a transformer.

Referring now to FIG. 4B, a perspective view illustration of a core 405 with a capacitor IPD 420 is shown, in accordance with an embodiment. In an embodiment, the capacitor IPD 420 comprises a pair of vertically oriented plates 425_{A} and 425_{B}. The core 405 may function as the dielectric between the conductive plates 425_{A} and 425_{B}. In an embodiment, the vertically oriented plates 425_{A} and 425_{B} may be formed with a laser-assisted etching process, such as described in greater detail above. The vertically oriented plates 425_{A} and 425_{B} may be referred to as via planes, similar to the embodiment described above with respect to FIG. 2A.

In an embodiment, the conductive plates 425_{A} and 425_{B} may extend into and through the entire thickness of the core 405. In other embodiments, the conductive plates 425_{A} and 425_{B} may extend partially through a thickness of the core 405. Such embodiments may be referred to as blind via planes, since they do not pass through the entire thickness of the core 405. In the illustrated embodiment, the conductive plates 425_{A} and 425_{B} have substantially vertical sidewalls. However, it is to be appreciated that the sidewalls of the conductive plates 425_{A} and 425_{B} may have sloped sidewalls or an hourglass shaped cross-section that is characteristic of laser-assisted etching processes. The laser-assisted etching process allows for a close spacing between the conductive plates 425_{A} and 425_{B} in order to provide higher capacitances. For example, a spacing between the conductive plates 425_{A} and 425_{B} may be approximately 40 μm or less or approximately 30 μm or less.

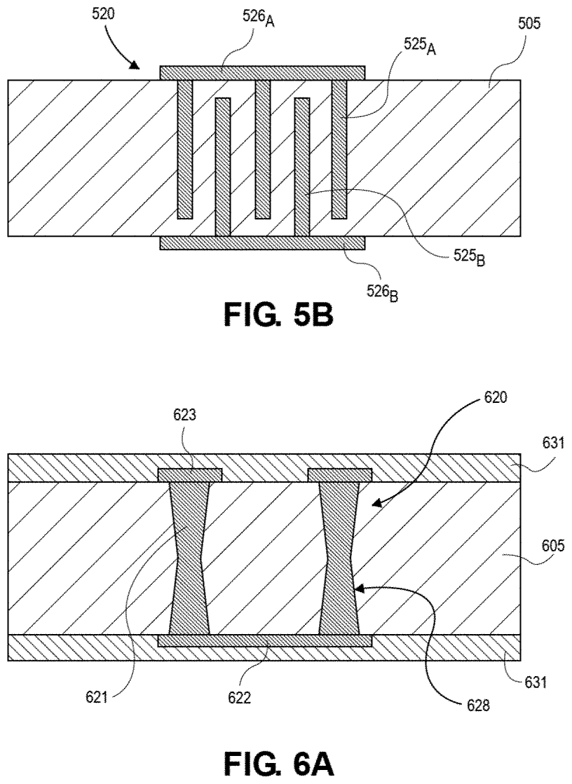

The laser-assisted patterning process also provides significant flexibility in the structure of the IPDs. For example, IPDs with different inductances or capacitances may be easily fabricated within a single core. An example of one such configuration is shown in FIG. 5A.

Referring now to FIG. 5A, a cross-sectional illustration of core 505 with a plurality of capacitor IPDs 520₁-520₃ is shown, in accordance with an embodiment. In an embodiment, each of the capacitor IPDs 520₁-520₃ have conductive plates 525_{A} and 535_{B} with different dimensions. That is, capacitor IPD 520₁ has a first height Hi and a first spacing S₁, capacitor IPD 520₂ has a second height H₂ and a second spacing S₂, and capacitor IPD 520₃ has a third height H₃ and a third spacing S₃. The heights H may all be different from each other, and the spacings S may all be different from each other. Additionally, the length of the conductive plates 525_{A} and 525_{B} (i.e., into and out of the plane of FIG. 5A) may be different from each other as well. As such, there are many different nobs that can be controlled to provide capacitor IPDs 520 with various capacitance values needed by the functional circuitry.

Referring now to FIG. 5B, a cross-sectional illustration of a core 505 with a capacitor IPD 520 is shown, in accordance with an additional embodiment. Instead of having a single pair of parallel plates, the capacitor IPD 520 in FIG. 5B includes interdigitated plates 525_{A} and 525_{B}. The plates 525_{A} may be electrically coupled together by a trace 526_{A} on a top surface of the core 505, and the plates 525_{B} may be electrically coupled together by a trace 526_{B} on a bottom surface of the core 505. In such an embodiment, the interdigitated plates 525_{A} and 525_{B} may be blind features that do not extend all the way through the thickness of the core 505. For example, the plates 525_{A} may enter the core 505 from the top surface and extend towards, but not to, the bottom surface, and the plates 525_{B} may enter the core 505 from the bottom surface and extend towards, but not to, the top surface.

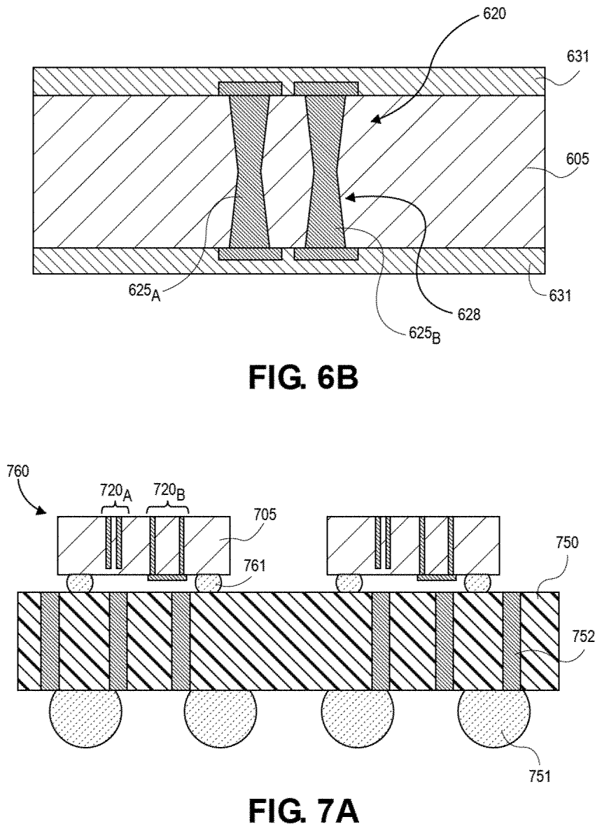

Referring now to FIGS. 6A and 6B, cross-sectional illustrations of IPDs 620 are shown, in accordance with additional embodiments. The embodiments shown in FIGS. 6A and 6B may more closely resemble cross-sections of actual devices fabricated in a glass core using a laser-assisted etching process.

Referring now to FIG. 6A, a cross-sectional illustration of a turn in an inductor IPD 620 is shown, in accordance with an embodiment. In an embodiment, the turn comprises a pair of vias 621 that pass through a thickness of the core 605. The vias 621 may be electrically coupled together by a trace 622 on a bottom surface of the core 605. The trace 622 may also be provided in the buildup layer 631 in some embodiments. The vias 621 may be electrically coupled to other turns of the inductor IPD 620 by traces 623 that extend into and out of the plane of FIG. 6A.

As shown in FIGS. 6A, the vias 621 may have sloped sidewalls 628. The slope of the sidewalls 628 may be approximately 10° or less. In some embodiments, the sidewalls 628 may have oppositely sloped sidewalls 628 that provide an hourglass shaped cross-section. Such embodiments may be characteristic of a laser-assisted etching process that includes laser exposure on both sides of the core 605. While an hourglass shaped cross-section is shown in FIG. 6A, it is to be appreciated that in other embodiments a single continuous slope may be provided along the sidewalls 628.

As shown in FIG. 6A, the sidewalls 628 of the vias 621 are in direct contact with the core 605. This is the result of the laser-assisted etching process, in which via openings are directly patterned into the core 605. That is, the inductor IPD 620 is not a discrete device that is subsequently embedded in a recess into the core 605. Instead, the inductor IPD 620 is formed as an integral part of the core 605.

Referring now to FIG. 6B, a cross-sectional illustration of a capacitor IPD 620 is shown, in accordance with an embodiment. In an embodiment, the capacitor IPD 620 may comprise a pair of vertically oriented plates 625_{A} and 625_{B}. The plates 625_{A} and 625_{B} may extend into and out of the plane of FIG. 6B to provide via planes. In an embodiment, the plates 625_{A} and 625_{B} may have sidewalls 628 that are sloped. The slope of the sidewalls 628 may be approximately 10° or less. In some embodiments, the sidewalls 628 may have oppositely sloped sidewalls 628 that provide an hourglass shaped cross-section. Such embodiments may be characteristic of a laser-assisted etching process that includes laser exposure on both sides of the core 605. While an hourglass shaped cross-section is shown in FIG. 6B, it is to be appreciated that in other embodiments a single continuous slope may be provided along the sidewalls 628.

As shown in FIG. 6B, the sidewalls 628 of the plates 625_{A} and 625_{B} are in direct contact with the core 605. This is the result of the laser-assisted etching process, in which plate openings are directly patterned into the core 605. That is, the capacitor IPD 620 is not a discrete device that is subsequently embedded in a recess into the core 605. Instead, the capacitor IPD 620 is formed as an integral part of the core 605.

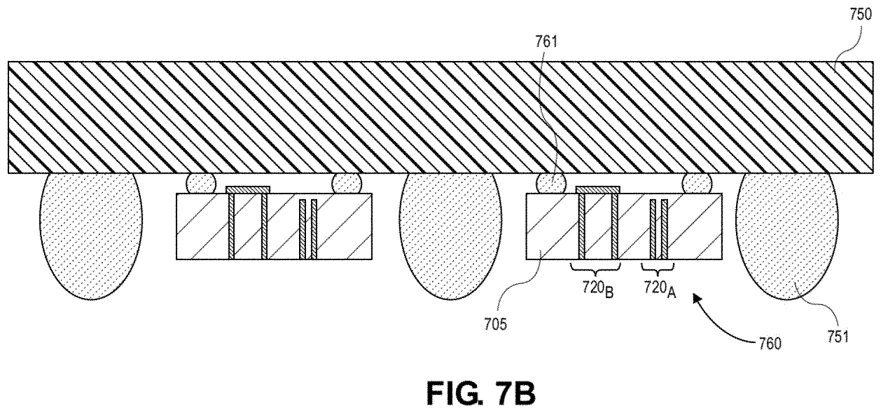

In the Figures set forth above, the IPDs are provided in a core of a package substrate. However, it is to be appreciated that IPDs in accordance with embodiments described herein are not limited to such architectures. In additional embodiments, the IPDs may be part of discrete systems. The discrete systems may be directly coupled to an active die in some embodiments. Examples of such embodiments are shown in FIGS. 7A and 7B.

Referring now to FIG. 7A, a cross-sectional illustration of an active die 750 is shown, in accordance with an embodiment. The active die 750 may be a processor, a radio transceiver, an SoC, a graphics processor, a memory, or any other type of die. In an embodiment, FLIs 751 may be provided on a bottom surface of the active die 750. Through substrate vias (TSVs) 752 may provide electrical connections between a top surface of the active die 750 and the bottom surface of the active die 750.

In an embodiment, discrete IPD systems 760 may be electrically coupled to a top surface of the active die 750 by interconnects 761, such as solder balls or the like. In an embodiment, the discrete IPD systems 760 may comprise a glass core 705. Various IPDs 720 may be embedded in the glass core 705. For example, a first IPD 720_{A} may be a capacitor, and a second IPD 720_{B} may be an inductor. The capacitor IPD 720_{A} may comprise a pair of parallel plates that extend into and out of the plane of FIG. 7A to form via planes. The inductor IPD 720_{B} may comprise a turn formed from vertical vias that are connected by a trace. The vertical vias may be coupled to other turns out of the plane of FIG. 7A by traces (not shown) on the top surface of the core 705. The capacitor IPD 720_{A} and the inductor IPD 720_{B} may be formed in the glass core 705 with a laser-assisted etching process, similar to embodiments described in greater detail above. As shown, a plurality of discrete IPD systems 760 may be attached to a single active die 750. While shown with both a capacitor IPD 720_{A} and an inductor IPD 720_{B}, it is to be appreciated that the discrete IPD system 760 may comprise one or both of the capacitor IPD 720_{A} and the inductor IPD 720_{B}, and can have any number of either the capacitor IPD 720_{A} and the inductor IPD 720_{B}.

Referring now to FIG. 7B, a cross-sectional illustration of another active die 750 is shown, in accordance with an additional embodiment. In an embodiment, the discrete IPD systems 760 may be connected to the bottom side of the active die 750 (i.e., on the same surface as the FLIs 751). Such an embodiment may provide the benefit of not needing TSVs. Additionally, cooling configurations are improved since the entire backside of the active die 750 is exposed. As such, an integrated heat spreader (IHS) or the like can be more easily placed over the surface of the active die 750. Similar to the embodiment shown in FIG. 7A, the discrete IPD system 760 may comprise one or both of a capacitor IPD 720_{A} and an inductor IPD 720_{B}, and can have any number of either the capacitor IPD 720_{A} and the inductor IPD 720_{B}.

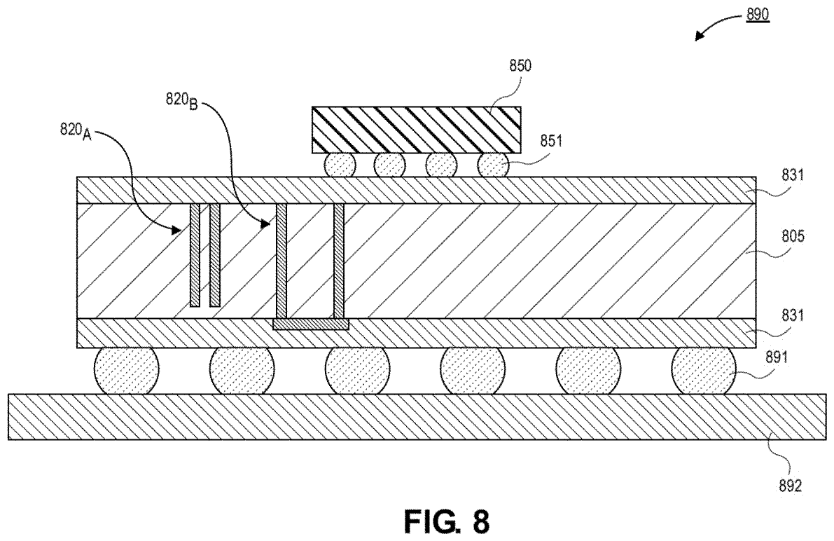

Referring now to FIG. 8, a cross-sectional illustration of an electronic system 890 is shown, in accordance with an embodiment. In an embodiment, the electronic system 890 may comprise a board 892, such as a printed circuit board (PCB). A package substrate may be coupled to the board 892 by second level interconnects 891. The second level interconnects 891 may comprise solder balls, sockets, or the like. In an embodiment, the package substrate comprises a core 805 with buildup layers 831 above and below the core 805.

In an embodiment, IPDs 820 may be embedded in the core 805. For example, IPDs 820 may comprise a capacitor IPD 820_{A} and an inductor IPD 820_{B}. Other IPDs, such as additional capacitors, additional inductors, transformers, and the like may also be embedded within the core 805. The IPDs 820 may be fabricated with a laser-assisted etching process. As such, the conductive features of the IPDs 820 may be in direct contact with the core 805. That is, the IPDs 820 are not discrete components that are embedded in a recess of the core 805. While shown with substantially vertical sidewalls, it is to be appreciated that sidewalls of the IPDs 820 may be sloped or hourglass shaped, as described above.

In an embodiment, the electronic system 890 may further comprise a die 850 that is coupled to a buildup layer 831 by FLIs 851. The FLIs 851 may comprise solder balls, copper bumps, or the like. In an embodiment, the die 850 may be any type of die, such as, but not limited to, a processor, an SoC, a graphics processor, a memory, or the like.

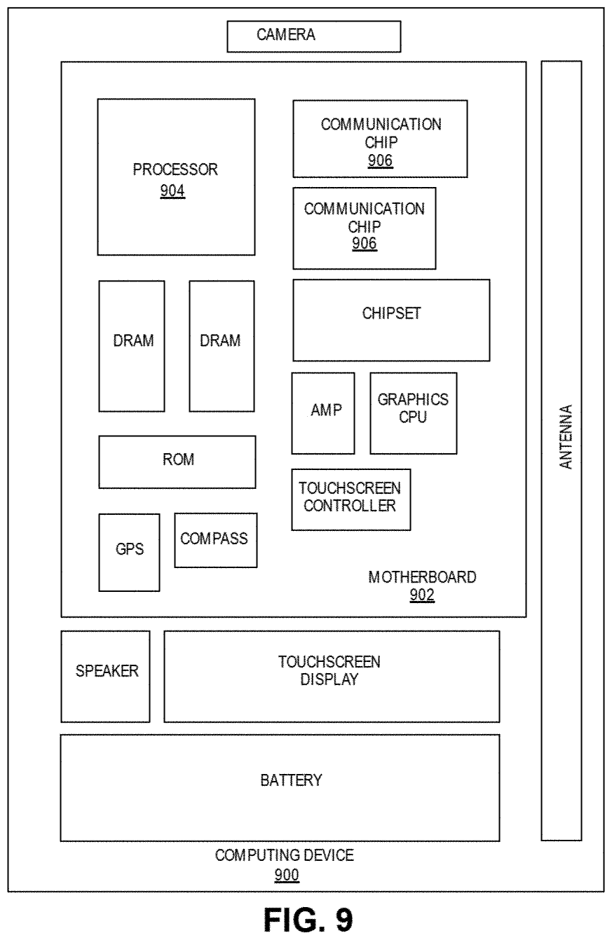

FIG. 9 illustrates a computing device 900 in accordance with one implementation of the invention. The computing device 900 houses a board 902. The board 902 may include a number of components, including but not limited to a processor 904 and at least one communication chip 906. The processor 904 is physically and electrically coupled to the board 902. In some implementations the at least one communication chip 906 is also physically and electrically coupled to the board 902. In further implementations, the communication chip 906 is part of the processor 904.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 906 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 906. For instance, a first communication chip 906 may be dedicated to shorter range wireless communications such as Wi-Fi and Bluetooth and a second communication chip 906 may be dedicated to longer range wireless communications such as GPS, EDGE, GPRS, CDMA, WiMAX, LTE, Ev-DO, and others.

The processor 904 of the computing device 900 includes an integrated circuit die packaged within the processor 904. In some implementations of the invention, the integrated circuit die of the processor may be part of an electronic package that comprises a package substrate with a core and vertically oriented passives embedded within the core, in accordance with embodiments described herein. The term “processor” may refer to any device or portion of a device that processes electronic data from registers and/or memory to transform that electronic data into other electronic data that may be stored in registers and/or memory.

The communication chip 906 also includes an integrated circuit die packaged within the communication chip 906. In accordance with another implementation of the invention, the integrated circuit die of the communication chip may be part of an electronic package that comprises a package substrate with a core and vertically oriented passives embedded within the core, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a package substrate, comprising: a glass core; and a vertically oriented inductor embedded in the glass core, wherein the inductor comprises vertical vias through the glass core, and wherein the vertical vias are electrically coupled together by conductive traces over a surface of the glass core to provide a plurality of conductive turns.

Example 2: the package substrate of Example 1, wherein the vias have a sloped sidewalls.

Example 3: the package substrate of Example 2, wherein cross-sections of the vias are hourglass shaped.

Example 4: the package substrate of Examples 1-3, wherein the vertical vias are extended to form vertical via planes.

Example 5: the package substrate of Examples 1-4, wherein the conductive traces are embedded in buildup layers over the glass core.

Example 6: the package substrate of Examples 1-5, wherein the plurality of conductive turns comprises three or more turns.

Example 7: a package substrate, comprising: a glass core; and a vertically oriented capacitor embedded in the glass core, wherein the capacitor comprises: a first plane into the glass core; and a second plane into the glass core.

Example 8: the package substrate of Example 7, wherein the first plane and the second plane pass entirely through a thickness of the glass core.

Example 9: the package substrate of Example 7 or Example 8, wherein the capacitor further comprises: a third plane into the glass core, wherein the third plane is coupled to the first plane by a first trace on a first surface of the glass core; and a fourth plane into the glass core, wherein the fourth plane is coupled to the second plane by a second trace on a second surface of the glass core.

Example 10: the package substrate of Example 9, wherein the second plane and the fourth plane are interdigitated with the first plane and the third plane.

Example 11: the package substrate of Examples 7-10, wherein sidewalls of the first plane and the second plane are sloped.

Example 12: the package substrate of Example 11, wherein cross-sections of the first plane and the second plane are hourglass shaped.

Example 13: the package substrate of Examples 7-12, further comprising: a second capacitor embedded in the glass core, wherein the second capacitor comprises: a third plane into the glass core; and a fourth plane into the glass core, wherein a height of the third plane and the fourth plane is different than a height of the first plane and the second plane.

Example 14: the package substrate of Example 13, wherein a spacing between the first plane and the second plane is different than a spacing between the third plane and the fourth plane.

Example 15: a package substrate, comprising: a glass core; and a vertically oriented passive component embedded in the core, wherein the passive component is in direct contact with the glass core.

Example 16: the package substrate of Example 15, wherein the passive component is an inductor with a plurality of turns, wherein planes of individual ones of the plurality of turns are substantially orthogonal to a top surface of the glass core.

Example 17: the package substrate of Example 15, wherein the passive component is a capacitor, wherein the capacitor comprises: a first plane into the glass core; and a second plane into the glass core.

Example 18: the package substrate of Example 15, wherein the passive component comprises one or more vias into the glass core, and wherein sidewalls of the vias are sloped.

Example 19: the package substrate of Example 18, wherein a cross-section of the vias is an hourglass shape.

Example 20: the package substrate of Examples 15-19, further comprising: a second vertically oriented passive component embedded in the glass core.

Example 21: the package substrate of Example 20, wherein the passive component is an inductor, and wherein the second passive component is a capacitor.

Example 22: an electronic system, comprising: a board; a package substrate coupled to the board, wherein the package substrate comprises: a glass core; and a vertically oriented passive component embedded in the glass core; and a die coupled to the package substrate.

Example 23: the electronic system of Example 22, wherein the passive component is an inductor.

Example 24: the electronic system of Example 22, wherein the passive component is a capacitor.

Example 25: the electronic system of Examples 22-24, wherein sidewalls of the passive component are sloped.

What is claimed is:

1. A package substrate, comprising:
a glass core; and
a vertically oriented inductor embedded in the glass core, wherein the inductor comprises vertical vias through the glass core, and wherein the vertical vias are electrically coupled together by conductive traces over a surface of the glass core to provide a plurality of conductive turns.

2. The package substrate of claim 1, wherein the vias have a sloped sidewalls.

3. The package substrate of claim 2, wherein cross-sections of the vias are hourglass shaped.

4. The package substrate of claim 1, wherein the vertical vias are extended to form vertical via planes.

5. The package substrate of claim 1, wherein the conductive traces are embedded in buildup layers over the glass core.

6. The package substrate of claim 1, wherein the plurality of conductive turns comprises three or more turns.

7. A package substrate, comprising:
a glass core; and
a vertically oriented capacitor embedded in the glass core, wherein the capacitor comprises:
a first plane into the glass core; and
a second plane into the glass core.

8. The package substrate of claim 7, wherein the first plane and the second plane pass entirely through a thickness of the glass core.

9. The package substrate of claim 7, wherein the capacitor further comprises:
a third plane into the glass core, wherein the third plane is coupled to the first plane by a first trace on a first surface of the glass core; and
a fourth plane into the glass core, wherein the fourth plane is coupled to the second plane by a second trace on a second surface of the glass core.

10. The package substrate of claim 9, wherein the second plane and the fourth plane are interdigitated with the first plane and the third plane.

11. The package substrate of claim 7, wherein sidewalls of the first plane and the second plane are sloped.

12. The package substrate of claim 11, wherein cross-sections of the first plane and the second plane are hourglass shaped.

13. The package substrate of claim 7, further comprising:
a second capacitor embedded in the glass core, wherein the second capacitor comprises:
a third plane into the glass core; and
a fourth plane into the glass core, wherein a height of the third plane and the fourth plane is different than a height of the first plane and the second plane.

14. The package substrate of claim 13, wherein a spacing between the first plane and the second plane is different than a spacing between the third plane and the fourth plane.

15. A package substrate, comprising:
a glass core; and
a vertically oriented passive component embedded in the core, wherein the passive component is in direct contact with the glass core.

16. The package substrate of claim 15, wherein the passive component is an inductor with a plurality of turns, wherein planes of individual ones of the plurality of turns are substantially orthogonal to a top surface of the glass core.

17. The package substrate of claim 15, wherein the passive component is a capacitor, wherein the capacitor comprises:
a first plane into the glass core; and
a second plane into the glass core.

18. The package substrate of claim 15, wherein the passive component comprises one or more vias into the glass core, and wherein sidewalls of the vias are sloped.

19. The package substrate of claim 18, wherein a cross-section of the vias is an hourglass shape.

20. The package substrate of claim 15, further comprising:
a second vertically oriented passive component embedded in the glass core.

21. The package substrate of claim 20, wherein the passive component is an inductor, and wherein the second passive component is a capacitor.

22. An electronic system, comprising:
a board;
a package substrate coupled to the board, wherein the package substrate comprises:
a glass core; and
a vertically oriented passive component embedded in the glass core; and
a die coupled to the package substrate.

23. The electronic system of claim 22, wherein the passive component is an inductor.

24. The electronic system of claim 22, wherein the passive component is a capacitor.

25. The electronic system of claim 22, wherein sidewalls of the passive component are sloped.
